(19) United States
(12) Patent Application Publication
(10) Pub. No.: US 2018/0142355 A1
(43) Pub. Date: May 24, 2018

(54) SYSTEM INTEGRATING ATOMIC LAYER DEPOSITION AND REACTIVE ION ETCHING

(71) Applicant: ADNANOTEK CORP., NEW TAIPEI CITY (TW)

(72) Inventors: KAI YANG, NEW TAIPEI CITY (TW); SHANG-YUNG PAI, NEW TAIPEI CITY (TW)

(21) Appl. No.: 15/356,444

(22) Filed: Nov. 18, 2016

(51) Int. Cl. C23C 16/50; H01J 37/32; C23C 16/455; H01L 21/02; H01L 21/3065

(52) U.S. Cl. CPC C23C 16/50; H01J 37/32082; H01J 2237/334; H01L 21/0228; H01L 21/3065; C23C 16/45544

(57) ABSTRACT

The instant disclosure provides a system integrating atomic layer deposition (ALD) and reaction ion etching (RIE) including a reaction device and a sample moving device. The reaction device includes a first reaction chamber and a second reaction chamber communicated to the first reaction chamber. The sample moving device is disposed in the reaction device, wherein a sample is controlled by the sample moving device and moves into the first reaction chamber for conducting atomic layer deposition or moves into the second reaction chamber for conducting reactive ion etching.

### BACKGROUND

### 1. Technical Field

The instant disclosure relates to a semiconductor manufacturing system, in particular, to a system integrating atomic layer deposition and reactive ion etching.

### 2. Description of Related Art

Atomic layer deposition (ALD) is a common manufacturing process in the semiconductor industry. ALD comprises inputting gaseous precursors impulsively and alternatively into a reaction chamber, and stacking atoms layer by layer through the saturated chemisorption and self-limiting occurring at the surface of the sample, thereby completing the deposition and the growth of thin films. In addition, plasma enhanced atomic layer deposition can be performed by the assistance of plasma. This technique comprises initiating the reaction of the precursors absorbed on the surface of the sample by plasma to form thin films. The advantage of the atomic layer deposition process is that the thin films manufactured therefrom have excellent covering uniformity and compliance.

Another common technique in the semiconductor industry is reactive ion etching (RIE). RIE comprises inputting specific process gases into the reaction chamber and transforming the gases into plasma (for example, by applying voltages between two electrode plates or generating plasma by electromagnetic induction) for etching the surface of the sample using the plasmas. Specifically, RIE comprises physical and chemical etching: physical etching is achieved by the impacts of the charged ions and electrons of the plasmas which are accelerated by the difference of electric potential produced by the electrode plates, the impacts result in the atoms at the surface of the sample being hit out; chemical etching is achieved by the chemical reaction between the various ions produced by the ionization of etching gases caused by the plasma and the samples (such as thin films or wafers). Since the RIE incorporates both physical etching and chemical etching, it has become the mainstream in the semiconductor manufacturing industry.

ALD and RIE are both procedures important to the semiconductor manufacturing process, and the existing plasma-enhanced atomic layer deposition (PEALD) and reaction ion etching system are two systems that operate separately and independently. Therefore, if there is a need to perform both procedures in one semiconductor manufacturing process, the sample needs to be transferred between two different systems, thereby increasing the manufacturing time and the risk of damage or pollution to the samples. In addition, the purchase of two independent systems will increase the cost of manufacturing and maintenance.

Accordingly, there is a need to provide a semiconductor manufacturing system which incorporates atomic layer deposition and reactive ion etching processes for avoiding the risks related to sample transferring and for significantly reducing manufacturing cost.

### SUMMARY

The object of the instant disclosure is to provide a system integrating atomic layer deposition and reactive ion etching. The system provided by the instant disclosure has a specific design to integrate two systems that are conventionally operated independently and separately in order to avoid the disadvantages of the manufacturing process and to reduce the manufacturing cost.

An exemplary embodiment of the present disclosure provides a system integrating atomic layer deposition and reactive ion etching, the system comprises a reaction device and a sample moving device. The reaction device comprises a first reaction chamber and a second reaction chamber connected to the first reaction chamber. The sample moving device is disposed in the reaction device, wherein a sample is controlled by the sample moving device to move into the first reaction chamber and conduct atomic layer deposition or move into the second reaction chamber and conduct reactive ion etching.

Preferably, the sample moving device comprises a mounting stage for carrying the sample and a moving structure connected to the mounting stage.

Preferably, when the sample is controlled by the sample moving device and moves into the first reaction chamber and conducts atomic layer deposition, the mounting stage carrying the sample is located in the first reaction chamber, and the first reaction chamber is communicated to the second reaction chamber.

Preferably, when the sample is controlled by the sample moving device, and moves into the second reaction chamber and conducts reactive ion etching, the mounting stage carrying the sample is located in the second reaction chamber, and the mounting stage insulates the first reaction chamber from the second reaction chamber, and the first reaction chamber and the second reaction chamber are not communicated to each other.

Preferably, the reaction device further comprises a first inlet tube communicated to the first reaction chamber, and a second inlet tube communicated to the second reaction chamber, an atomic layer deposition gas is input into the first reaction chamber through the first inlet tube, and a reaction ion etching gas is input into the second reaction chamber through the second inlet tube.

Preferably, the reaction device has a plasma generator disposed outside of the second reaction chamber, the plasma generator transferring the reactive ion etching gas into plasma during the reactive ion etching, or performing plasma enhanced atomic layer deposition during the atomic layer deposition.

Preferably, the reaction device has a plasma generator, the plasma generator comprising a pair of electrode plate disposed inside of the second reaction chamber for transferring the reactive ion etching gas into a plasma during the reactive ion etching, or performing plasma enhanced atomic layer deposition during the atomic layer deposition

Preferably, the reaction device further comprises a heater disposed in the first reaction chamber for heating the sample during atomic layer deposition.

Preferably, the sample moving device further comprises a cooling circuit for cooling the sample during reactive ion etching.

Preferably, the sample moving device further comprises a radio frequency bias cable for applying a radio frequency power or a bias to the sample.

Preferably, the reaction device further comprises an outlet tube for controlling the pressure in the first reaction chamber and the second reaction chamber of the reaction device.

Preferably, the reaction device further comprises a local heater for locally heating the sample before performing atomic layer deposition or reactive ion etching.

Preferably, the local heater generates a focused electron beam or a laser for locally heating the sample.

To sum up, the advantages of the instant disclosure reside in that the system integrating atomic layer deposition and reactive ion etching comprises the specific structure design of the sample moving device which controls the sample to move into the first reaction chamber for conducting atomic layer deposition or move into the second reaction chamber for conducting reactive ion etching and hence, the atomic layer deposition procedure and the reactive ion etching procedure can be carried out in the same reaction device. Therefore, the risk of damage and pollution on the sample related to sample transfer is avoided and the equipment cost is significantly reduced.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1 is a sectional schematic view of the system integrating atomic layer deposition and reaction ion etching provided by the embodiments of the instant disclosure under a first state.

FIG. 2 is a sectional schematic view of the system integrating atomic layer deposition and reaction ion etching provided by the embodiments of the instant disclosure under a second state.

FIG. 3 is another implementation of the system integrating atomic layer deposition and reaction ion etching provided by the embodiments of the instant disclosure.

FIG. 4 is yet another implementation of the system integrating atomic layer deposition and reaction ion etching provided by the embodiments of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

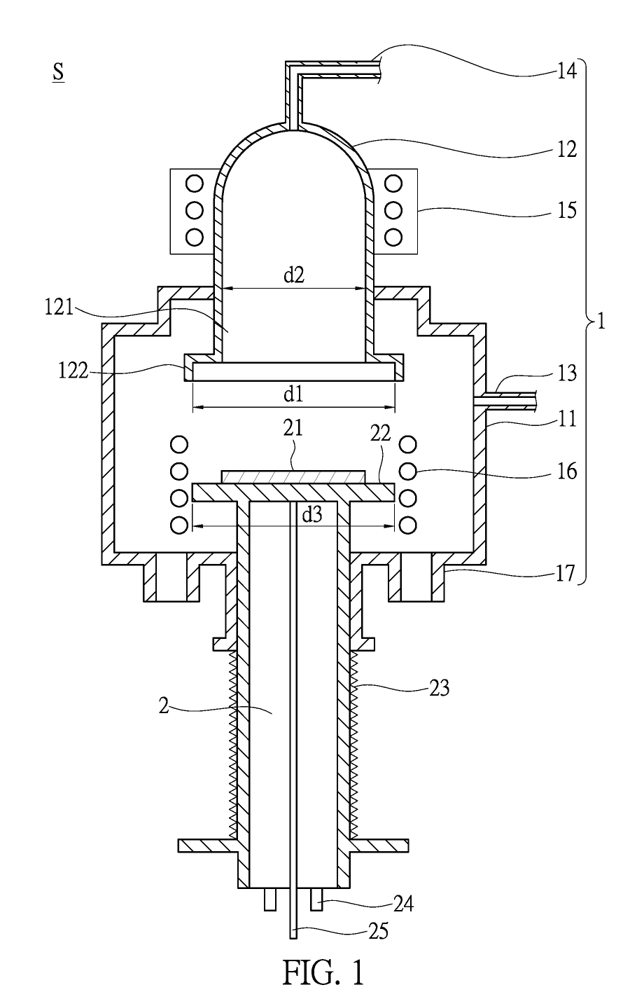

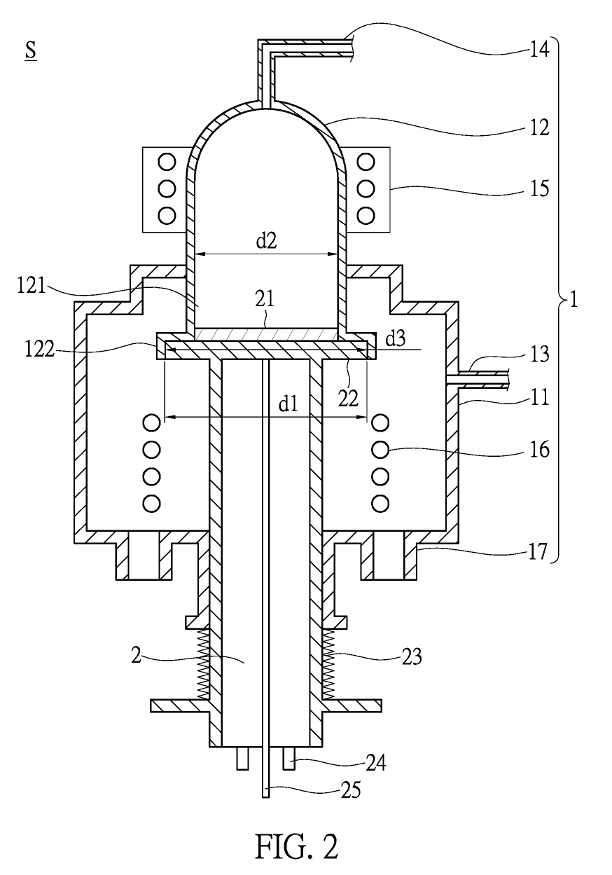

Please refer to FIG. 1 and FIG. 2. FIG. 1 and FIG. 2 are sectional schematic views of the system integrating atomic layer deposition and reactive ion etching provided by the embodiments of the instant disclosure under different states. The system integrating atomic layer deposition and reactive ion etching S provided by the instant disclosure comprises a reaction device 1 and a sample moving device 2. The sample moving device 2 is disposed in the reaction device 1 and electrically connected to a control unit (not shown).

Specifically, the reaction device 1 comprises a first reaction chamber 11 and a second reaction chamber 12, and the first reaction chamber 11 and the second reaction chamber 12 are connected to each other. For example, the first reaction chamber 11 and the second reaction chamber 12 are cylindrical vacuum chambers. However, the instant disclosure is not limited thereto. In the embodiments of the instant disclosure, the walls of the first reaction chamber 11 and the second reaction chamber 12 can overlap with each other, and the first reaction chamber 11 is sleeved into the second reaction chamber 12. In other words, a part of the first reaction chamber 11 is located inside of the second reaction chamber 12. As shown in FIG. 1 and FIG. 2, the first reaction chamber 11 is located at the bottom part of the reaction device 1, and the second reaction chamber 12 is located at the upper part of the reaction device 1.

The second reaction chamber 12 comprises a main part 121 and a chamber opening 122. In the instant disclosure, a part of the main part 121 of the second reaction chamber 12 and the chamber opening 122 are located inside of the first reaction chamber 11. The shape of the first reaction chamber 11 is not limited in the instant disclosure. In the present embodiment, the chamber opening 122 is a circular opening and has an inner diameter d1. In the embodiments of the instant disclosure, the inner diameter d1 of the chamber opening 122 is larger than the inner diameter d2 of the main part 121. Under the first state (as shown in FIG. 1), the first reaction chamber 11 and the second reaction chamber 12 are communicated to each other through the chamber opening 122. The function of the chamber opening 122 under the second state is described later.

The sample moving device 2 is disposed in the reaction device 1 for controlling the movement of the sample 21, i.e., for moving the sample 21 into the first reaction chamber 11 to conduct atomic layer deposition or moving the sample 21 into the second reaction chamber 12 to conduct reaction ion etching. FIG. 1 and FIG. 2 show the system integrating atomic layer deposition and reactive ion etching S under the states of performing the atomic layer deposition and reactive ion etching respectively. In other words, in FIG. 1, the sample 21 is moved into the first reaction chamber 11 for performing atomic layer deposition, and in FIG. 2, the sample 21 is moved into the second reaction chamber 12 for performing reactive ion etching.

For example, the sample 21 is a semiconductor substrate such as a substrate made of silicon. The sample moving device 2 comprises a mounting stage 22 for carrying the sample 21 and a moving structure 23 connected to the mounting stage 22. The moving structure 23 of the sample moving device 2 can control the mounting stage 22 to move along the Z axis (i.e., upward and downward). In addition, in the instant disclosure, the mounting stage 22 is a disc and the diameter d3 of the mounting stage 22 and the inner diameter d1 of the chamber opening 122 of the second reaction chamber 12 are substantially the same. Accordingly, when the mounting stage 22 moves upwardly into the second reaction chamber 12 by the moving structure 23, the mounting stage 22 fits in the chamber opening 122 of the second reaction chamber 12 and insulates the first reaction chamber 11 from the second reaction chamber 12.

Please refer to FIG. 1 and FIG. 2. The reaction device 1 further comprises a first inlet tube 13 communicated to the first reaction chamber 11 and a second inlet tube 14 communicated to the second reaction chamber 12. For example, as shown in FIG. 1, the first inlet tube 13 is directly communicated to the first reaction chamber 11 for inputting an atomic layer deposition gas into the first reaction chamber 11. Alternatively, in other embodiments, the first inlet tube 13 can be disposed at the chamber opening 122 of the second reaction chamber 12 and hence, the atomic layer deposition gas input from the first inlet tube 13 enters the first reaction chamber 11 through the chamber opening 122 of the second reaction chamber 12. Under this situation, the gas input from the first inlet tube 13 can be uniformly distributed onto the surface of the sample 21 by passing through a porous mesh (not shown) optionally disposed above the chamber opening 122 of the second reaction chamber 12. The second inlet tube 14 is connected to the upper part of the second reaction chamber 12 for inputting a reactive ion etching gas into the second reaction chamber 12. The location of the second inlet tube 14 can be adjusted according to actual needs. In the embodiment shown in FIG. 1 and FIG. 2, the second inlet tube 14 is connected to the upper part of the main part 121 of the second reaction chamber 12.

In the instant disclosure, the first inlet tube 13 and the second inlet tube 14 do not input the atomic layer deposition gas and the reactive ion etching gas simultaneously into the reaction device 1. In other words, the atomic layer deposition gas is input through the first inlet tube 13 while performing atomic layer deposition, and the reactive ion etching gas is input through the second inlet tube 14 while performing reactive ion etching.

In addition, the system integrating atomic layer deposition and reactive ion etching S provided by the instant disclosure further comprises a discharging tube 17 for controlling the pressure in the first reaction chamber 11 and the second reaction chamber 12 of the reaction device 1. The discharging tube 17 is disposed at the bottom of the reaction device 1, i.e., the lower end of the first reaction chamber 11 of the reaction device 1. For example, the discharging tube 17 is connected to a vacuum pump for vacuuming the first reaction chamber 11 and/or the second reaction chamber 12.

Please refer to FIG. 1 and FIG. 2. The details of the atomic layer deposition process and the reactive ion etching process performed by the system integrating atomic layer deposition and reactive ion etching S provided by the instant disclosure are described below.

First, please refer to FIG. 1. FIG. 1 shows the state of performing atomic layer deposition by the system integrating atomic layer deposition and reactive ion etching S provided by the instant disclosure. When the sample 21 is controlled by the sample moving device 2 and moves into the first reaction chamber 11 for conducting atomic layer deposition, the mounting stage 22 carrying the sample 21 is located in the first reaction chamber 11, and the first reaction chamber 11 and the second reaction chamber 12 are communicated to each other.

The first reaction chamber 11 of the reaction device 1 is a reaction chamber for performing atomic layer deposition. As described above, an atomic layer deposition gas can be input into the first reaction chamber 11 through the first inlet tube 13 communicated to the first reaction chamber 11. The atomic layer deposition gas comprises precursors for performing atomic layer deposition. For example, when a zinc oxide layer is deposed, the atomic layer deposition gas can comprise zinc-containing precursors and oxygen-containing precursors. The zinc-containing precursors can comprise, diethyl zinc ((C₂H₅)₂Zn) or dimethyl zinc ((CH₃)₂Zn), and the oxygen-containing precursors can comprise water (H₂O), ozone (O₃) and/or oxygen (O₂). However, the species contained in the atomic layer deposition gas can be selected according to actual needs and are not limited in the instant disclosure.

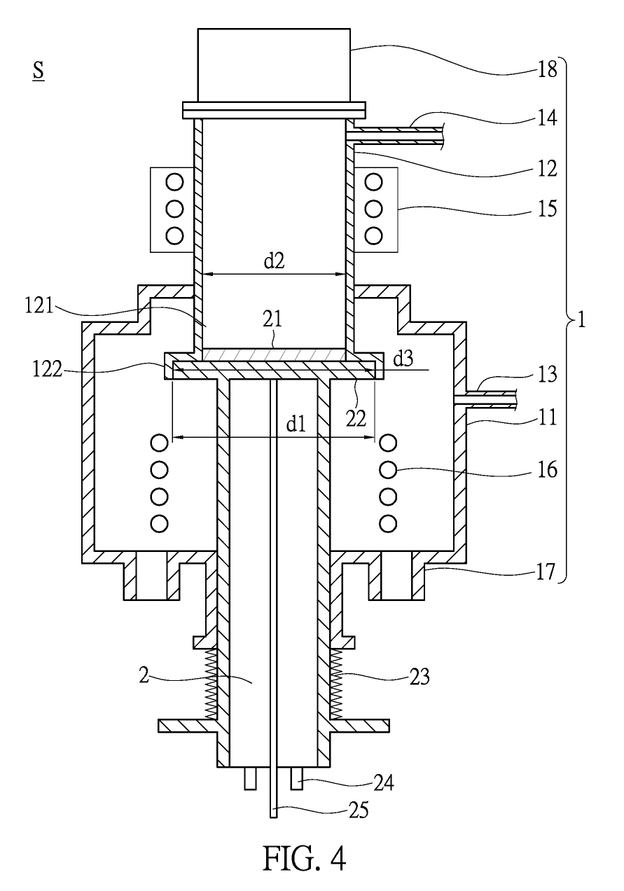

Since the mechanism of atomic layer deposition is highly related to temperature, during the atomic layer deposition process, the reaction temperature should be well-controlled. Therefore, the reaction device 1 of the system integrating atomic layer deposition and reactive ion etching S of the instant disclosure comprises a heater 16 disposed in the first reaction chamber 11 for heating the sample 21 during the atomic layer deposition process. For example, the heater 16 used in the instant disclosure is a laser, an electron beam source or an X-ray source. In addition, in the system integrating atomic layer deposition and reactive ion etching S shown in FIG. 4, a local heater 18 is further disposed as an assisted heating source, such as a focused laser or a focused electron beam gun. Different from the conventional manufacturing equipment that directly disposes the heater in the mounting stage carrying the sample, the system integrating atomic layer deposition and reactive ion etching S provided by the instant disclosure includes the heater 16 disposed in the first reaction chamber 11.

In other words, in the system of the instant disclosure, the heater 16 and the mounting stage 22 are disposed separately. Since the location of the sample 21 is determined by the sample moving device 2 (i.e., in the first reaction chamber 11 or in the second reaction chamber 12), if the heater 16 is located inside the mounting stage 22, when the sample 21 is moved into the second reaction chamber 12 for conducting reactive ion etching, the heater 16 may be damaged or corroded by the reactive ion etching gas.

In addition, the reaction device 1 can further comprise a plasma generator 15 disposed outside the second reaction chamber 12 for conducting plasma enhanced atomic layer deposition (PEALD). The plasma generator 15 can further comprise a plurality of coils surrounding the second reaction chamber 12 and an electric power supply electrically connected to the coils (not shown, such as a radio frequency generator). Alternatively, the plasma generator 15 comprises a pair of electrode plate disposed inside of the second reaction chamber 12. The plasma generator 15 is used to form a plasma discharging area, and to control the plasma density and ion flux in the reaction device 1 by controlling the energy applied to the coils.

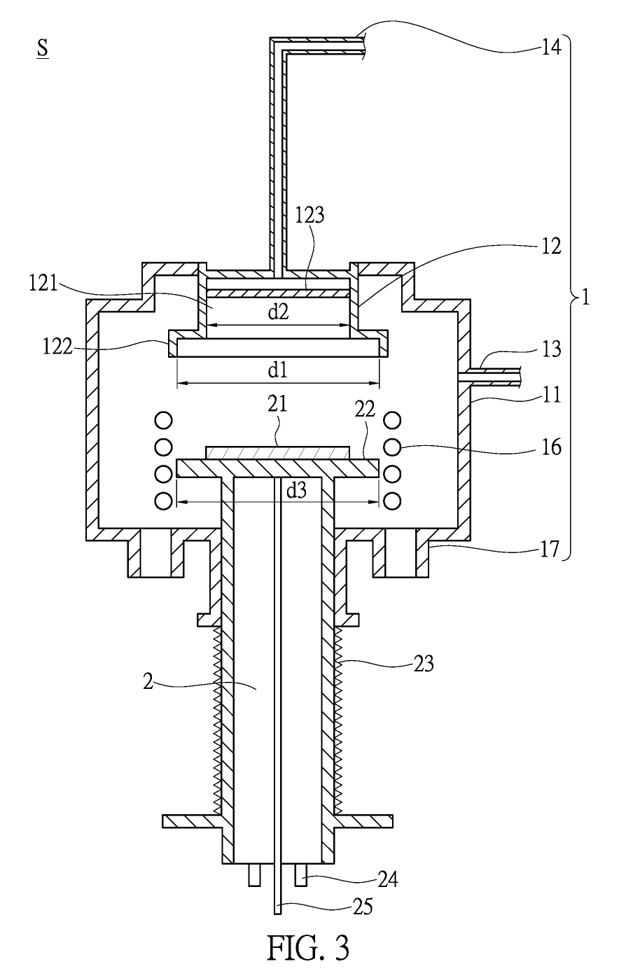

In addition, as shown in FIG. 3, in another implementation of the system integrating atomic layer deposition and reactive ion etching S provided by the instant disclosure, the reaction device 1 can generate plasma through a porous mesh 123 for conducting reactive ion etching. The porous mesh 123 is a metallic plate with micro-pores, such as an aluminum alloy plate with micro-pores.

As described above, the sample 21 is controlled by the sample moving device 2 to move into the first reaction chamber 11 for conducting atomic layer deposition, the mounting stage 22 carrying the sample 21 is located in the first reaction chamber 11, and the first reaction chamber 11 and the second reaction chamber 12 are communicated to each other. Therefore, when the atomic layer deposition gas is input into the reaction device 1, the atomic layer deposition gas enters the second reaction chamber 12 located at the upper part of the reaction device 1. The plasma generator 15 disposed outside of the second reaction chamber 12 forms a plasma discharging area in the second reaction chamber 12 for providing the plasma for plasma assisted atomic layer deposition.

In sum, when performing the atomic layer deposition process, plasmas can be generated by the plasma discharging area formed in the second reaction chamber 12, and the atom layer deposition process is performed on the surface of the sample 21 in the first reaction chamber 11. During the atomic layer deposition process on the surface of the sample 21, the reaction temperature of the sample 21 can be well-controlled by the heater 16 in the first reaction chamber 11. In addition, nitrogen gas or other inert gases (such as argon) can be used to purge the first inlet tube 13 to avoid the interference between different atomic layer deposition gases.

Please refer to FIG. 2. FIG. 2 shows the state of performing reactive ion etching of the system integrating atomic layer deposition and reactive ion etching S provided by the instant disclosure. When the sample 21 is controlled by the sample moving device 2 to move into the second reaction chamber 12 for conducting reactive ion etching, the mounting stage 22 carrying the sample 21 is located inside the second reaction chamber 12, and the mounting stage 22 insulates the first reaction chamber 11 from the second reaction chamber 12.

As shown in FIG. 2, when the mounting stage 22 carrying the sample 21 is moved into the second reaction chamber 12 by the moving structure 23 of the sample moving device 2, the mounting stage 22 fits the chamber opening 122 of the second reaction chamber 12. As described above, the inner diameter d1 of the chamber opening 122 of the second reaction chamber 12 is equal to the diameter d3 of the mounting stage 22. Therefore, during the reactive ion etching process, the mounting stage 22 is used to separate and insulate the first reaction chamber 11 from the second reaction chamber 12. Therefore, the reactive ion etching gas for performing reactive ion etching process will not flow into the first reaction chamber 11 and damage the heater 16 inside of the first reaction chamber 11.

The type of the reactive ion etching gas is selected according to the material of the sample 21 and the etching process. For example, if the sample 21 is a silicon substrate, the reactive ion etching gas can be fluorine-based gas such as sulphur hexafluoride, carbon tetrafluoride (CF₄), trifluoromethane (CHF₃), hexafluoroethane (C₂F₆) or octafluoropropane (C₃F₈).

When the sample 21 is located in the second reaction chamber 12, a plasma discharge area can be generated by the plasma generator 15 disposed outside of the second reaction chamber 12. For example, high-density plasma can be generated by the radio frequency powered magnetic field produced by the plasma generator 15. However, the etching profile formed through the above means is more isotropic and hence, the sample moving device 2 of the instant disclosure further comprises a radio frequency bias cable 25 to apply a radio frequency power or a bias to the sample 21. The radio frequency bias cable 25 is used to provide insulation of the sample 21 and achieve a more anisotropic etching profile by applying a directional electric field onto the sample 21.

Please refer to FIG. 2. The sample moving device 2 of the instant disclosure further comprises a cooling circuit 24 for cooling the sample 21 during the reactive ion etching process. Specifically, cooling water can be input into the cooling circuit 24, or gases such as helium can be input into the cooling circuit 24 to reduce the temperature of the sample 21. When using cooling water to cool the sample 21, a water outlet valve is additionally disposed to discharge the cooling water of the cooling circuit 24 during the atomic layer deposition process.

In sum, during the reactive ion etching process, the mounting stage 22 carrying the sample 21 is used to insulate the first reaction chamber 11 from the second reaction chamber 12, and the etching process is performed on the surface of the sample 21 in the second reaction chamber 12. Therefore, the heater 16 in the first reaction chamber 11 is prevented from the corrosion caused by the reactive ion etching gas. In addition, during the etching process on the surface of the sample 21, the cooling circuit 25 disposed in the sample moving device 2 can control the reaction temperature of the sample 21.

In addition, the system integrating atomic layer deposition and reactive ion etching S provided by the instant disclosure further comprises the local heater 18 for locally heating the sample before performing the atomic layer deposition process or the reactive ion etching process. Generally, in a conventional process, a patterning process must be performed on the surface of the sample 21 by other equipment to produce a sample 21 with patterns, and after the follow-up coating process is completed, the photo-etching paste for forming the pattern must be removed. Therefore, if the user intended to form multiple different patterns on the sample 21 or to pattern the newly-formed film layer, the sample must be transported to other equipment outside of the reaction chamber and subject to a masking processes. Therefore, the complexity and time of the process increase, and the risk or damaging the sample 21 is increased as well.

In order to solve above problem, the system integrating atomic layer deposition and reactive ion etching S provided by the instant disclosure comprises the local heater 18 which is a focused electron beam or a laser, and the local heater 18 locally heats the sample 21 (heats the predetermined area on the surface of the sample 21). Please refer to FIG. 4. The local heater 18 is a focused laser or a focused electron beam disposed on the top end of the system integrating atomic layer deposition and reactive ion etching S. Therefore, by locally heating predetermined locations of the sample 21 to a pre-set temperature for conducting the growth of thin films or conducting an etching process, the instant disclosure can achieve the effect of selective film-forming or selective etching.

In summary, the effectiveness of the instant disclosure is that the system integrating atomic layer deposition and reactive ion etching S provided by the instant disclosure which includes the structure design of the reaction device 1 and the sample moving device 2, i.e., the sample moving device 2 is disposed in the reaction device 1 for controlling the sample 21 to move into the first reaction chamber 11 for conducting atomic layer deposition or move into the second reaction chamber 12 for conducting reactive ion etching, is able to perform the atomic layer deposition process and the reactive ion etching in the same reaction device 1.

Specifically, the system integrating atomic layer deposition and reactive ion etching S not only employs the sample moving device 2 to move the sample 21 to suitable reaction locations, but also employs the specific design of the components of the reaction device 1 and the sample moving device 2 to perform plasma-assisted atomic layer deposition process by using the plasma generator 15 outside of the second reaction chamber 12 during the atomic layer deposition process. During the reactive ion etching, by isolating the first reaction chamber 11 and the second reaction chamber 12 from each other, the instant disclosure is able to prevent the heater 16 in the first reaction chamber 11 from the damages caused by the reactive ion etching gas.

At last, the system integrating atomic layer deposition and reactive ion etching S provided by the instant disclosure further comprises the local heater 18 for achieving selective film-formation or etching.

The above-mentioned descriptions represent merely the exemplary embodiment of the present disclosure, without any intention to limit the scope of the instant disclosure thereto. Various equivalent changes, alterations or modifications based on the claims of the instant disclosure are all consequently viewed as being embraced by the scope of the instant disclosure.

What is claimed is:

1. A system integrating atomic layer deposition and reactive ion etching, comprising:
a reaction device comprising a first reaction chamber and a second reaction chamber connected to the first reaction chamber; and
a sample moving device disposed in the reaction device, wherein a sample is controlled by the sample moving device to move into the first reaction chamber and conduct atomic layer deposition or move into the second reaction chamber and conduct reactive ion etching.

2. The system integrating atomic layer deposition and reactive ion etching according to claim 1, wherein the sample moving device comprises a mounting stage for carrying the sample and a moving structure connected to the mounting stage.

3. The system integrating atomic layer deposition and reactive ion etching according to claim 2, wherein when the sample is controlled by the sample moving device to move into the first reaction chamber and conduct atomic layer deposition, the mounting stage carrying the sample is located in the first reaction chamber, and the first reaction chamber is communicated to the second reaction chamber.

4. The system integrating atomic layer deposition and reactive ion etching according to claim 2, wherein when the sample is controlled by the sample moving device to move into the second reaction chamber and conduct reactive ion etching, the mounting stage carrying the sample is located in the second reaction chamber, the mounting stage insulates the first reaction chamber from the second reaction chamber, and the first reaction chamber and the second reaction chamber are not communicated to each other.

5. The system integrating atomic layer deposition and reactive ion etching according to claim 1, wherein the reaction device further comprises a first inlet tube communicated to the first reaction chamber and a second inlet tube communicated to the second reaction chamber, wherein an atomic layer deposition gas is input into the first reaction chamber through the first inlet tube, and a reaction ion etching gas is input into the second reaction chamber through the second inlet tube.

6. The system integrating atomic layer deposition and reactive ion etching according to claim 5, wherein the reaction device has a plasma generator disposed outside of the second reaction chamber, the plasma generator transferring the reactive ion etching gas into a plasma during the reactive ion etching, or performing plasma enhanced atomic layer deposition during the atomic layer deposition.

7. The system integrating atomic layer deposition and reactive ion etching according to claim 5, wherein the reaction device has a plasma generator, the plasma generator comprising a pair of electrode plate disposed inside of the second reaction chamber for transferring the reactive ion etching gas into a plasma during the reactive ion etching, or performing plasma enhanced atomic layer deposition during the atomic layer deposition.

8. The system integrating atomic layer deposition and reactive ion etching according to claim 1, wherein the reaction device further comprises a heater disposed in the first reaction chamber for heating the sample during atomic layer deposition.

9. The system integrating atomic layer deposition and reactive ion etching according to claim 1, wherein the sample moving device further comprises a cooling circuit for cooling the sample during reactive ion etching.

10. The system integrating atomic layer deposition and reactive ion etching according to claim 1, wherein the sample moving device further comprises a radio frequency bias cable for applying a radio frequency power or a bias to the sample.

11. The system integrating atomic layer deposition and reactive ion etching according to claim 1, wherein the reaction device further comprises an outlet tube for controlling the pressure in the first reaction chamber and the second reaction chamber of the reaction device.

12. The system integrating atomic layer deposition and reactive ion etching according to claim 1, wherein the reaction device further comprises a local heater for locally heating the sample before performing atomic layer deposition or reactive ion etching.

13. The system integrating atomic layer deposition and reactive ion etching according to claim 12, wherein the local heater generates a focused electron beam or a laser for locally heating the sample.
